(19) United States
(12) Patent Application Publication
(10) Pub. No.: US 2026/0267095 A1
(43) Pub. Date: Sep. 10, 2026

(54) IMMERSION COOLING-COMPATIBLE MULTIMODE OPTICAL MODULE

(71) Applicant: Cisco Technology, Inc., San Jose, CA (US)

(72) Inventors: Michael TITTENHOFER, Fuerth (DE); Yi TANG, San Jose, CA (US); Li DING, Pleasanton, CA (US); Stephen A. SCEARCE, Apex, NC (US)

(21) Appl. No.: 19/071,579

(22) Filed: Mar. 5, 2025

(51) Int. Cl. G02B 6/42; H01L 23/44; H01L 25/16

(52) U.S. Cl. CPC G02B 6/4248; G02B 6/4214; G02B 6/428; H10W 40/30; H10W 90/00

(57) ABSTRACT

Optical modules are provided. In one aspect, an optical module includes a printed circuit board (PCB) and a cover having a flange coupled with the PCB. The PCB and the cover are sealed such that when the PCB and the cover are disposed in an immersion fluid the PCB and the cover collectively define a sealed interior that is fluidly isolated from the immersion fluid. The optical module also includes an optical fiber and an electro-optical package disposed in the sealed interior. The electro-optical package has a lens body providing an optical path along which optical signals travel. The optical fiber is in free space optical communication with the optical path of the lens body. A fiber escape is formed by the flange and the PCB, allowing the optical fiber to escape the sealed interior into the immersion fluid.

### TECHNICAL FIELD

The present disclosure generally relates to optical modules, and more specifically, to optical modules that are cooled by immersion fluid.

### BACKGROUND

While immersion cooling can offer significant benefits for data centers, it presents certain challenges, particularly for optical modules. One difficulty arises from the reliance on free space gaps and refraction to couple light from an optical component of the optical module to an optical fiber (or vice versa). An immersion cooling fluid can interfere with these optical pathways, disrupting the precise alignment and refraction needed for efficient light transmission. Further, some optical modules have their electrical interface and/or electrical transmission lines exposed to the immersion fluid, which can lead to less than desirable signal integrity due to the immersion fluid undergoing phase changes during operation (e.g., from liquid to gas or vice versa). Also, some optical modules have architectures that can limit the number of routing resources, namely because the electrical transmission lines are typically routed from a hermetically sealed area over one edge of the package through a pass through. Further, material incompatibility can pose a hurdle. Some materials used in optical modules can degrade or break down when exposed to immersion cooling fluids. This degradation can compromise the integrity and performance of the optical components, leading to potential failures and reduced reliability.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1A is a top plan view of an optical module according to one or more aspects of the present disclosure.

FIG. 1B is a schematic cross-sectional view of the optical module taken along section line A-A in FIG. 1A.

FIG. 2A is a schematic cross-sectional view of an optical module according to one or more aspects of the present disclosure.

FIG. 2B is a schematic cross-sectional view of an optical module according to one or more aspects of the present disclosure.

FIG. 3 is a schematic cross-sectional view of an optical module according to one or more aspects of the present disclosure.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

In one aspect, an optical module is provided. The optical module includes a printed circuit board (PCB); a cover having a flange coupled with the PCB, wherein the PCB and the cover are sealed such that when the PCB and the cover are disposed in an immersion fluid the PCB and the cover collectively define a sealed interior that is fluidly isolated from the immersion fluid; an optical fiber; a modulator; and a lens body disposed in the sealed interior and providing an optical path along which optical signals travel, wherein the optical fiber is in free space optical communication with the optical path of the lens body and the modulator is in free space optical communication with the optical path. A fiber escape is formed by the flange and the PCB, allowing the optical fiber to escape the sealed interior into the immersion fluid.

In another aspect, an optical module is provided. The optical module includes a printed circuit board (PCB); a carrier package that includes an interconnect and a carrier having at least one electrically-conductive layer; an optical fiber; a cover coupled with the carrier and having a fiber dock that receives the optical fiber and defines a free space channel to provide free space optical communication between the optical fiber and a dock lens of the fiber dock, wherein the carrier and the cover are sealed such that when the PCB, the carrier, and the cover are disposed in an immersion fluid, the carrier and the cover collectively define a sealed interior that is fluidly isolated from the immersion fluid; and an electro-optical package disposed in the sealed interior, the electro-optical package having a lens body, a modulator, and an electrical integrated circuit (EIC) arranged on, and electrically coupled with, the carrier, wherein the lens body provides an optical path that is in free space optical communication with the dock lens and in free space optical communication with the modulator. An electrical path is defined between the EIC and the PCB, at least in part, by the carrier and the interconnect.

In yet another aspect, an optical module is provided. The optical module includes a printed circuit board (PCB); an optical fiber; and an electro-optical package having a modulator and a lens body mounted on the PCB. When the lens body and the PCB are disposed in an immersion fluid, external surfaces of the lens body and the PCB are exposed to the immersion fluid. The lens body and the PCB collectively define an enclosure in which the modulator is arranged and which is sealed such that when the lens body and the PCB are disposed in immersion fluid, the enclosure is fluidly isolated from the immersion fluid. Further, the lens body provides a guided optical path along which optical signals travel between a first lens and a second lens of the lens body. The lens body defines a free-space channel that allows the optical fiber to be in free space optical communication with the first lens, the free-space channel being filled with an optical fluid that is fluidly isolated from, and different than, the immersion fluid. The second lens is in free space optical communication with the modulator. The lens body has a reflective surface disposed along the guided optical path and arranged to change a direction of optical signals, the reflective surface having a coated backing that fluidly isolates the immersion fluid from the reflective surface.

### Example Embodiments

Various optical modules that are compatible with immersion cooling are disclosed herein. In at least one example, an immersion cooling-compatible optical module can include a printed circuit board (PCB), a cover coupled to the PCB, and an electro-optical package disposed within a sealed interior defined by the cover and the PCB. The optical module can be submerged in an immersion fluid, but the sealed interior can be fluidly isolated from the immersion fluid. The electro-optical package can include a modulator and a lens body that provides a guided optical path spanning between a first lens and a second lens. The cover and the PCB can provide a fiber escape to allow an optical fiber to escape from the sealed interior into the immersion fluid. The optical fiber can be a single optical fiber or can be one optical fiber of an optical fiber array. For instance, in one example, the optical fiber can be one of a plurality of optical fibers of a fiber ribbon. In yet another example, the optical fiber can be one of a plurality of optical fibers of a lens array, or lensed fiber array. The optical fiber can be received by the lens body and can be in free space optical communication with the first lens of the lens body. This free space optical coupling can enable travel of multimode optical signals along the guided optical path. The free space between the optical fiber and the first lens can be filled with an optical fluid, which is fluidly isolated from, and different than, the immersion fluid. The optical fluid can be any gaseous or liquid medium that supports optical properties. The second lens of the lens body can be in free space optical communication with the modulator. The free space between the second lens and the modulator can be filled with optical fluid, which is isolated from the immersion fluid. Moreover, the electro-optical package can include an electronic integrated circuit (EIC) electrically coupled with the modulator. The EIC can in turn be electrically coupled with electrical transmission lines that are buried within, and traverse through, the PCB, such as from a position underneath the cover to a position not underneath the cover. The buried transmission lines can be electrically coupled with various devices external to the sealed interior. Moreover, in at least one example, a compression plate can be added to a side of the PCB opposite the side to which the cover is mounted. Compression elements can be used to compress the cover and the compression plate toward one another

Advantageously, the architecture of such an optical module can provide free space optical coupling between the optical fiber and the lens body and between the lens body and the modulator, with both of these free space optical couplings being within optical fluid that is fluidly isolated from, and different than, the immersion fluid. In this manner, the properties of optical signals traveling through these free space regions can be unaffected by phase changes of the immersion fluid, which can be a dual-phase immersion fluid. Moreover, increased signal and power integrity can be achieved as the signal transmission lines spanning between the electro-optical package and the one or more devices external to the sealed interior are not exposed to the immersion fluid. In this way, the transmission lines can be unaffected by immersion fluid phase changes. Further, the architecture of such an optical module can provide a fiber escape for optical fibers through a sealed pathway between the cover and the PCB, which can simplify the cover design and can facilitate ease of assembly. In addition, compression of the cover and the compression plate toward one another can enhance sealing performance and can increase the structural stability of the optical module. Other advantages, benefits, and/or technical effects are contemplated.

In one or more other examples, an optical module can include a multilayer or single layer carrier package that can enclose the bottom portion of the sealed interior, rather than the PCB as in the example above. The cover can be coupled with a carrier of the package, rather than the PCB. Interconnects of such packages (e.g., soldered balls of a ball grid array or leadless interconnects) can be used to electrically couple the EIC with the PCB. Accordingly, increased routing resources can be provided and enhanced signal integrity can be achieved since long leads can be eliminated or reduced and immediate transition into the inner layers can be accomplished.

In one or more further examples, an optical module can include a “coverless” architecture. That is, the cover can be omitted and the immersion fluid can directly contact the external surfaces of the lens body, which can increase cooling performance. In such examples, a reflective surface of the lens body, which changes the direction of optical signals traveling along the guided optical path, can include a coating to prevent or reduce interference of the immersion fluid with the optical signals. Moreover, the architecture of such an optical module can provide free space optical coupling between the optical fiber and the lens body and between the lens body and the modulator, with both of these free space optical couplings being within optical fluid that is fluidly isolated from, and different than, the immersion fluid. In this way, multimode optical signals can travel along the guided optical path of the lens body and the free space optical couplings can be shielded from negative impacts from phase changes of the immersion fluid.

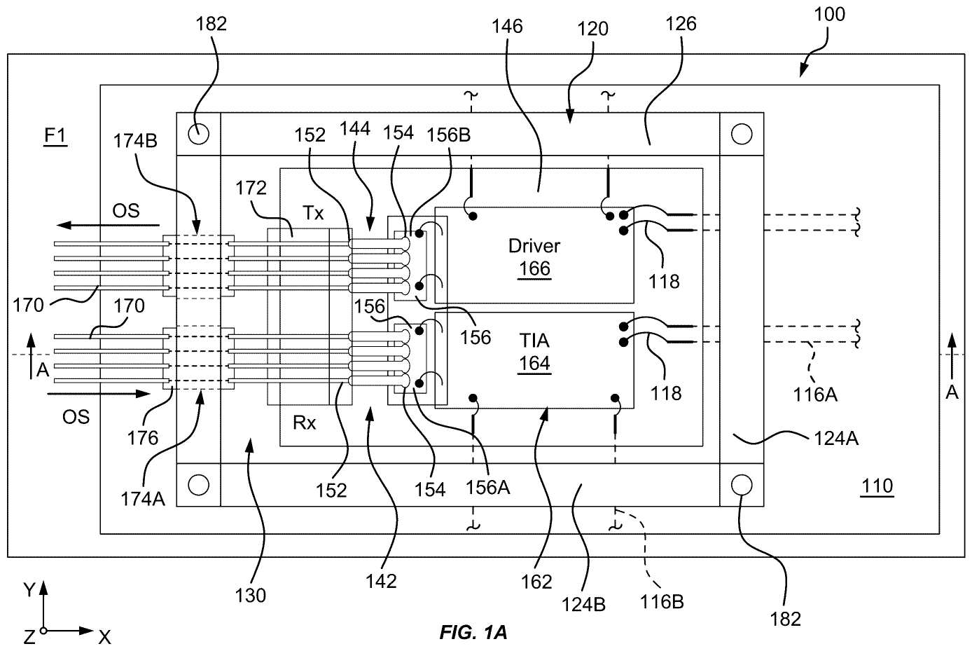

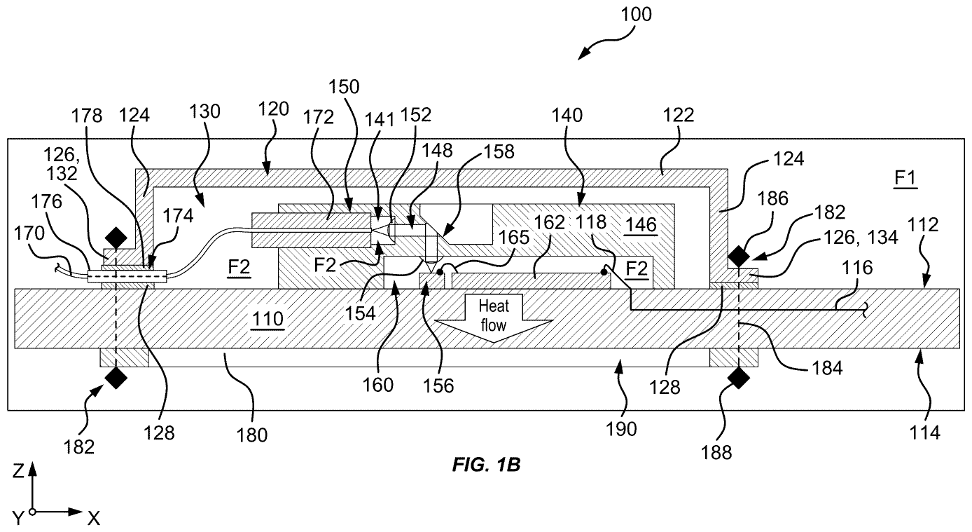

Turning now to the drawings and with reference to FIGS. 1A and 1B, FIG. 1A is a top plan view of an optical module 100 according to one or more aspects of the present disclosure and FIG. 1B is a schematic cross-sectional view of the optical module 100 taken along section line A-A in FIG. 1A. The optical module 100 can used in a data center, for example. For reference, the optical module 100 defines an X-direction, a Y-direction, and a Z-direction, which are mutually perpendicular to one another. The X-direction can be a transverse direction, the Y-direction can be a lateral direction, and the Z-direction can be a vertical direction, for example.

As depicted in FIGS. 1A and 1B, the optical module 100 can include a printed circuit board (PCB), or PCB 110. The PCB 110 has a first side 112 (e.g., a top side) and a second side 114 (e.g., a bottom side) opposite the first side 112. The PCB 110 can be formed of an organic material, a ceramic material, a glass material, or some other suitable material. The optical module 100 can also include a cover 120 coupled with the PCB 110. In at least one example, the cover 120 can be a punched metal cover. In at least one example, the cover 120 can be formed as a single monolithic component. In other examples, the cover 120 can be formed by multiple components, such as by two shells.

The cover 120 has a top wall 122, a plurality of side walls 124 extending downward from the top wall 122, and a flange 126 that extends outward from the side walls 124. In at least one example, the flange 126 can extend from the side walls 124 and along an entirety of a perimeter of the cover 120. The flange 126 can be coupled with the PCB 110, e.g., by an adhesive and/or compression elements. A sealing gasket 128 can be used to seal the cover 120 to the PCB 110. The sealing gasket 128 can be arranged between the flange 126 and the PCB 110, e.g., along an entirety of the perimeter of the cover 120. The PCB 110 and the cover 120 can be disposed in an immersion fluid F1 and can collectively define a sealed interior 130. The sealed interior 130 can be sealed off from the immersion fluid F1.

In one or more examples, the immersion fluid F1 can be a two-phase dielectric fluid capable of taking on both liquid and gaseous states. The immersion fluid F1 can be circulated around or about the submerged optical module 100 passively or actively. In one or more examples, as shown in FIG. 1B, an optical fluid F2 can be disposed within the sealed interior 130. The optical fluid F2 can be any gaseous or liquid medium that supports optical properties, or rather, does not substantially impact optical properties of optical signals traveling in free space. The optical fluid F2 can be a different fluid than the immersion fluid F1. In at least one example, the optical fluid F2 within the sealed interior 130 can help prevent the immersion fluid F1 from entering the sealed interior 130.

The optical module 100 can include an electro-optical package 140 disposed in the sealed interior 130 and one or more optical fibers 170 linked to the electro-optical package 140 by one or more optical connectors 172 (e.g., ferrules, fiber array units, etc.). In FIG. 1A, a plurality of optical fibers 170 are shown extending into the sealed interior 130 and terminating at the one or more optical connectors 172. In FIG. 1B, only one of the optical fibers 170 is shown extending into the sealed interior 130 and terminating at its associated optical connector 172.

As shown in the example of FIGS. 1A and 1B, the electro-optical package 140 can include a receiver circuit 142 and a transmitter circuit 144. In this regard, a first set of the optical fibers 170 can be associated with the receiver circuit 142, e.g., to carry optical signals OS to the electro-optical package 140, and a second set of the optical fibers 170 can be associated with the transmitter circuit 144, e.g., to carry optical signals OS away from the electro-optical package 140. In the example of FIG. 1A, there are four (4) optical fibers 170 associated with the receiver circuit 142 and four (4) optical fibers associated with the transmitter circuit 144. In other examples, however, more or less than four (4) optical fibers can be associated with the receiver and/or transmitter circuits 142, 144.

The electro-optical package 140 can include a lens body 146. The lens body 146 can provide an optical path 148 along which optical signals can travel, e.g., between lenses thereof. In one or more examples, the lens body 146 can be formed of polyetherimide or another thermoplastic material. Accordingly, in such examples, the optical path 148 can be considered a guided optical path.

The lens body 146 can define a pocket 150 (or pockets) in which the optical connectors 172 of the optical fibers 170 can be received. In FIG. 1B, one of the optical connectors 172 is shown received within the pocket 150. The lens body 146 can also define a free-space channel 141 that is adjacent to the pocket 150. The free-space channel 141 can be filled with the optical fluid F2. The free-space channel 141 can allow for optical signals to travel in free space between the optical fibers 170 and the optical path 148. In at least one example, the lens body 146 can have one or more first lenses 152 disposed along the optical path 148. One of the first lenses 152 is depicted in FIG. 1B. The first lenses 152 can be arranged in free-space optical communication with respective ones of the optical fibers 170. The free-space channel 141 and the first lenses 152 can enable multimode optical signals to travel along the optical path 148. Indeed, the free-space channel 141 spaces the optical fibers 170 from the first lenses 152, e.g., by a distance along the X-direction, so that optical signals can expand from having relatively small diameters at the optical fibers 170 associated with the receiver circuit 142 to relatively larger diameters at the first lenses 152, which can collimate the optical signals for travel along the optical path 148. The first lenses 152 can focus the light from the optical path 148 to the optical fibers 170 associated with the transmitter circuit 144.

The lens body 146 can also include one or more second lenses 154 disposed along the optical path 148. One of the second lenses 154 is illustrated in FIG. 1B. The second lenses 154 can be arranged in free-space optical communication with a modulator 156 of the electro-optical package 140. The second lenses 154 can collimate or focus the light depending on the propagation direction. Further, the lens body 146 can include a reflective surface 158 disposed between the first and second lenses 152, 154 along the optical path 148 and arranged to change a direction of optical signals, e.g., by ninety degrees (90°). The lens body 146 and the PCB 110 can collectively define an enclosure 160, which is sealed off from the immersion fluid F1. In one or more examples, the optical fluid F2 can be disposed within the sealed interior 130.

The electro-optical package 140 further includes an electrical integrated circuit (EIC), or EIC 162, disposed within the enclosure 160 and arranged on, and electrically coupled with, the PCB 110. The EIC 162 can include a trans-impedance amplifier (TIA), or TIA 164, and a driver 166. The TIA 164 and the driver 166 can be on separate chips as shown in FIG. 1A or on a shared chip in other examples. The modulator 156 can include one or more photodetectors 156A and/or one or more light emitters 156B, such as VCSELs (vertical-cavity surface-emitting lasers). The modulator 156 can be electrically coupled with the EIC 162, e.g., by wire bonds 165, and can be optically coupled with the optical path 148. For instance, the photodetectors 156A of the modulator 156 can be components of the receiver circuit 142 and can convert incoming optical signals from the optical path 148 into electrical signals, which can be routed to the TIA 164 for processing, e.g., by wire bonds 165. The light emitters 156B can be components of the transmitter circuit 144 and can convert electrical signals received from the driver 166 into optical signals, which can be transmitted to the optical path 148 and to the optical fibers 170 associated with the transmitter circuit 144. Accordingly, the modulator 156 can be arranged to convert optical signals into electrical signals and electrical signals into optical signals.

In one or more examples, the EIC 162 can be directly mounted on the PCB 110. As shown in FIG. 1B, the heat generated by the electro-optical package 140, including by the EIC 162 and the modulator 156, can conduct through the thickness of the PCB 110 and can be imparted to the relatively cool immersion fluid F1. In this way, the thermal performance of the optical module 100 can be enhanced. In one or more examples, the second side 114 of the PCB 110 can be metal plated, e.g., to enhance the conductive heat transfer and to prevent or reduce vapor contaminate into the enclosure 160 and/or sealed interior 130.

In one or more examples, the PCB 110 can have one or more buried transmission lines 116. The buried transmission lines 116 can be electrically coupled with the EIC 162, e.g., by respective wire bonds 118 extending from the EIC 162, and can each be electrically coupled with other devices arranged external to the sealed interior 130. In at least one example, at least one of the buried transmission lines 116 can extend from a starting position underneath the cover 120 to an ending position not underneath the cover 120. In FIG. 1B, one of the buried transmission lines 116 is shown extending to a position not underneath the cover 120. In FIG. 1A, multiple buried transmission lines 116 are shown extending to respective positions that are not underneath the cover 120.

In at least one example, at least two of the buried transmission lines 116 can extend under different side walls of the cover 120, e.g., from respective starting positions underneath the cover 120 to respective positions not underneath the cover 120. By way of example, in FIG. 1A, a first buried transmission line 116A is shown extending along the X-direction underneath a first side wall 124A of the cover 120 and a second buried transmission line 116B is depicted extending along the Y-direction underneath a second side wall 124B of the cover 120. Stated another way, in at least one example, at least two of the buried transmission lines 116 can extend from under the cover 120 in different directions (such as directions that are perpendicular to one another, one to the right and one to the left, one to the front and one to the back, etc.). In one or more other examples, the buried transmission lines 116 can include at least a first buried transmission line, a second buried transmission line, and a third buried transmission line each extending under different side walls of the cover 120.

Advantageously, by burying the transmission lines within the PCB 110, more routing resources can be provided for high-speed data signals as well as for supply and control signals. Further, because the buried transmission lines 116 are buried, the buried transmission lines 116 do not extend through the cover 120 to reach their respective external positions, which can reduce transmission line bottle necks and the need for sealing elements at the cover 120. In addition, because the buried transmission lines 116 are buried, the buried transmission lines 116 are not exposed to phase changes associated with the immersion fluid F1 during operation.

In one or more examples, such as in the example of FIGS. 1A and 1B, the optical module 100 can include one or more “fiber escapes” that provide openings for the optical fibers 170 to escape from (or extend into) the sealed interior 130. One or more fiber escapes 174 can be formed between the flange 126 and the PCB 110, allowing the optical fibers 170 to escape the sealed interior 130. In the example of FIG. 1A, one fiber escape 174A is provided to allow one or more of the optical fibers 170 associated with the receiver circuit 142 to escape the sealed interior 130 and another fiber escape 174B is provided to allow the optical fibers 170 associated with the transmitter circuit 144 to escape the sealed interior 130.

In one or more examples, the flange 126 of the cover 120 can include one or more escape sections 132 that form, at least in part, the fiber escapes 174. The escape sections 132 can be arranged at a different height than a remainder of the flange 126, or rather, the mounting section 134 of the flange 126. As illustrated in FIG. 1B, the escape section 132 of the flange 126 is arranged further from the first side 112 of the PCB 110 than the mounting section 134 of the flange 126. The escape section 132 is arranged a distance D1 from the first side 112 of the PCB 110 and the mounting section 134 is arranged a distance D2 from the first side 112 of the PCB 110. The distance D1 is greater than the distance D2. Stated differently, the side wall 124 of the cover 120 to which the escape section 132 of the flange 126 extends is shorter than the side wall of the cover 120 to which the mounting section 134 of the flange 126 extends. In this regard, the bottom end of the side wall 124 to which the escape section 132 of the flange 126 extends is further away from the PCB 110 along the Z-direction than is the side wall of the cover 120 to which the escape section 132 of the flange 126 extends. Accordingly, the escape section 132 of the flange 126 enables the optical fiber 170 to pass through or escape from the sealed interior 130.

In one or more examples, a sleeve 176 can be arranged to protect one or more of the optical fibers 170 as the optical fibers 170 pass through one of the fiber escapes 174. In at least one example, the sleeve 176 can be formed of glass. In other examples, the sleeve 176 can be formed of a different material. The sleeve 176 can be encased, at least in part, by a sleeve gasket 178 so that the sealed interior 130 is sealed off from the immersion fluid F1 at the fiber escape 174. The sleeve gasket 178 can be positioned at least between the sleeve 176 and the cover 120, or more particularly, the escape section 132 of the flange 126.

Further, in one or more examples, the optical module 100 can include a compression plate 180 disposed on the side of the PCB 110 opposite the cover 120, or in this example, the second side 114 of the PCB 110. One or more compression elements 182 can compress the cover 120 and the compression plate 180 toward one another. In at least one example, the compression elements 182 can be arranged at the corners of the cover 120, e.g., as shown in FIG. 1A. The compression elements 182 can extend through the cover 120, the PCB 110, and the compression plate 180 to compress the cover 120 and the compression plate 180 toward one another.

In at least one example, the compression elements 182 can each include a shank 184 and first and second retainers 186, 188 (e.g., threaded nuts or inserts). The shank 184 can extend through the flange 126 of the cover 120, the PCB 110, and the compression plate 180. The first retainer 186 can be arranged to secure the shank 184 to the flange 126 and the second retainer 188 can be arranged to secure the shank 184 to the compression plate 180. In one or more examples, the retainers 186, 188 can be tightened to compress the cover 120 and the compression plate 180 toward one another, e.g., by torqueing the retainers 186, 188 along threading of the shank 184. In doing so, the sealing gasket 128 can also be compressed, sealing the sealed interior 130 from the immersion fluid F1.

In one or more examples, the compression plate 180 can form one or more openings that allow the immersion fluid F1 to directly contact the second side 114 of the PCB 110. For instance, as depicted in FIG. 1B, the compression plate 180 can have a rectangular shape forming an opening 190. Stated another way, the compression plate 180 can have a hollow rectangular shape. The opening 190 allows the immersion fluid F1 to directly contact the second side 114 of the PCB 110. In this manner, heat generated by the components of the electro-optical package 140 can conduct through the PCB 110 and can be imparted directly to the immersion fluid F1, which can enhance the transfer of heat away from the electro-optical package 140, and thus, performance can be increased.

To summarize, the architecture of the optical module 100 can advantageously provide free space optical coupling between the optical fibers 170 and the lens body 146 and between the lens body 146 and the modulator 156, with both of these free space optical couplings being within optical fluid F2 that is fluidly isolated from, and different than, the immersion fluid F1. This can enable the properties of optical signals traveling through these free space regions to be unaffected by phase changes of the immersion fluid F1, and can also facilitate the use of multimode optical signals. Moreover, increased signal and power integrity can be achieved by use of the buried transmission lines 116. Also, complete or more complete use of the PCB routing resources can be utilized. Further, the fiber escapes 174 can provide sealed pathways between the cover 120 and the PCB 110 for optical fibers 170 to traverse into or out of the sealed interior 130. These fiber escapes 174 are strategically located to simplify the cover design and to facilitate ease of assembly. In addition, compression of the cover 120 and the compression plate 180 toward one another can enhance sealing performance and can increase the structural stability of the optical module 100.

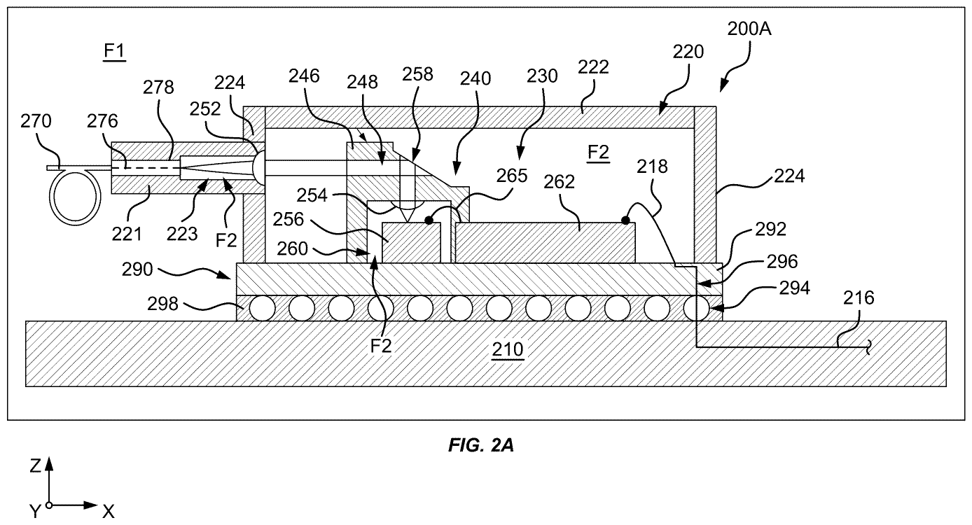

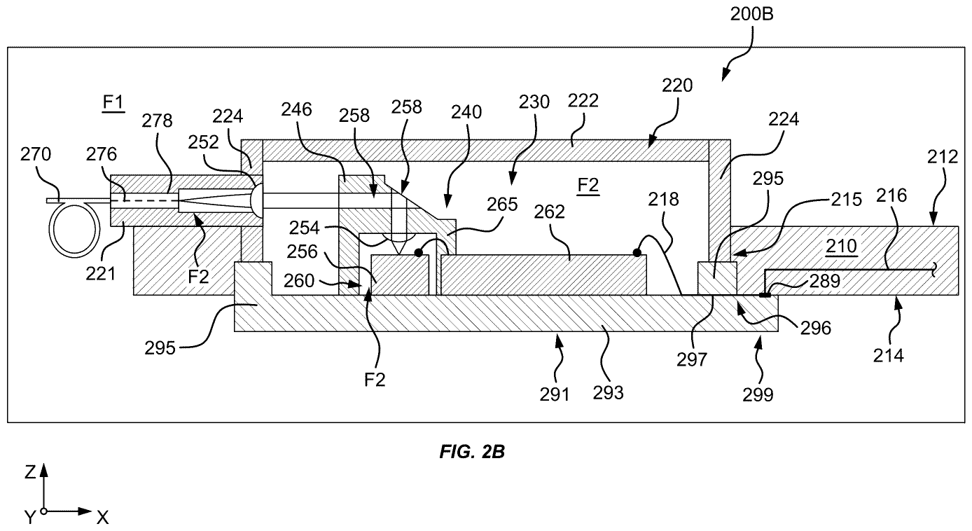

FIG. 2A is a schematic cross-sectional view of an optical module 200A according to one or more aspects of the present disclosure. The optical module 200A can be used in a data center, for example. As will be described below, the optical module 200A can include a hermetic metal cover arranged on a multilayer ball grid array (BGA) carrier, or multilayer BGA carrier. The metal cover can be added to the top of the multilayer BGA carrier, with one or more optical fibers feeding into the cover via a fiber dock. An electro-optical package can be preassembled and incorporated as a drop-in component during the assembly process.

As depicted in FIG. 2A, the optical module 200A can include, among other things, a PCB 210, a cover 220, and a BGA package 290. The BGA package 290 can have a multilayer carrier 292 and interconnects 294 carried by the multilayer carrier 292. The interconnects 294 can be electrically-conductive balls (e.g., solder balls), for example. The multilayer carrier 292 can include a substrate formed of a ceramic or glass material and a plurality of electrically-conductive layers (e.g., metal layers) disposed on or embedded therein. Electrically-conductive vias can extend between and connect the electrically-conductive layers. The BGA package 290 can be mounted on the PCB 210 by way of the interconnects 294. The interconnects 294 can electrically couple the PCB 210 and the multilayer carrier 292. The cover 220 can be coupled with the multilayer carrier 292. The PCB 210, the cover 220, and the BGA package 290 can be disposed in an immersion fluid F1. The multilayer carrier 292 and the cover 220 collectively define a sealed interior 230, which can be sealed off from the immersion fluid F1. The immersion fluid F1 can be a liquid coolant, such as water. In one or more examples, the immersion fluid F1 can be circulated around the submerged optical module 200A. In one or more examples, an optical fluid F2 can be disposed within the sealed interior 230.

The cover 220 can have a top wall 222 and a plurality of side walls 224 extending downward from the top wall 222. The side walls 224 can be attached (e.g., by bonding, gluing, etc.) to a top surface of the multilayer carrier 292. In at least one example, the cover 220 can be a punched metal cover. In at least one example, the cover 220 can be formed as a single monolithic component. In other examples, the cover 220 can be formed by multiple components.

The cover 220 can include a fiber dock 221 (or a plurality of fiber docks) arranged in one or more of the side walls 224. The fiber dock 221 can be hollow and can have a proximal end and a distal end. At the proximal end, the fiber dock 221 is arranged to receive at least a portion of an optical fiber 270. A sleeve 276 can be arranged to protect the optical fiber 270 within the fiber dock 221. In at least one example, the sleeve 276 can be formed of glass. In other examples, the sleeve 276 can be formed of a different material. In one or more examples, the sleeve 276 can be encased, at least in part, by a sleeve gasket 278. The fiber dock 221 can define a free-space channel 223 that allows for optical signals to travel between the optical fiber 270 and a first lens 252, or dock lens, disposed at the proximal end of the fiber dock 221. The sleeve gasket 278 can prevent immersion fluid F1 from entering the free-space channel 223.

The optical module 200A can also include an electro-optical package 240 disposed in the sealed interior 230. The electro-optical package 240 can have a lens body 246 providing at least part of an optical path 248. The lens body 246 can be formed of polyetherimide or another thermoplastic material, for example. Accordingly, in such examples, the optical path 248 can be considered a guided optical path.

The lens body 246 can include a second lens 254 (or a plurality of second lenses) disposed along the optical path 248. The second lens 254 can be arranged in direct optical communication with a modulator 256 of the electro-optical package 240. Further, the lens body 246 can include a reflective surface 258 disposed between the first and second lenses 252, 254 and arranged to change a direction of optical signals, e.g., by ninety degrees (90°). The lens body 246 and the multilayer carrier 292 can collectively define an enclosure 260, which is sealed off from the immersion fluid F1. In one or more examples, an optical fluid F2 can be disposed within the enclosure 260.

The electro-optical package 240 also includes an EIC 262 arranged on, and electrically coupled with, the multilayer carrier 292, e.g., by one or more wire bonds 218. The EIC 262 is also electrically coupled with the modulator 256, e.g., by one or more wire bonds 265. The modulator 256 can include one or more photodetectors, e.g., along a receiver circuit, and one or more light emitters, e.g., along a transmitter circuit. The modulator 256 can be arranged to convert optical signals into electrical signals and electrical signals into optical signals. The modulator 256 can be disposed within the enclosure 260, e.g., as shown in FIG. 2A.

An electrical path 296 along which electrical signals can travel can be defined between the EIC 262 and the PCB 210. The electrical path 296 can be defined, at least in part, by the multilayer carrier 292 and the interconnects 294 of the BGA package 290. In at least one example, one or more wire bonds 218 can electrically couple the EIC 262 with the multilayer carrier 292. One or more metal or electrically-conductive layers within the multilayer carrier 292 can allow electrical signals to travel through the thickness of the multilayer carrier 292, e.g., from the top side to the bottom side. The interconnects 294 can electrically couple the multilayer carrier 292 with the PCB 210. For instance, in FIG. 2A, one of the interconnects 294 is depicted electrically coupled with a buried transmission line 216, which is buried in the PCB 210. Accordingly, electrical signals can travel along the electrical path 296 from the EIC 262 to the PCB 210.

In at least one example, an underfill material 298 (e.g., a glob) can be applied between the multilayer carrier 292 and the PCB 210 to protect and surround the interconnects 294. In this regard, the immersion fluid F1 does not directly contact the interconnects 294. In other examples, the underfill material 298 can be omitted.

The architecture of the optical module 200A can advantageously provide increased signal and power integrity as the signal lines spanning between the electro-optical package 240 and one or more devices external to the sealed interior 230 are not in contact with the immersion fluid F1, and thus, are not or negligibly impacted by phase changes of the immersion fluid F1. That is, the signal lines are protected from the immersion fluid F1. Moreover, the BGA package 290 can provide increased routing resources (i.e., there can be many signal paths through respective ones of the interconnects 294) and enhanced signal integrity and power integrity can be achieved as immediate transition into inner layers is provided.

FIG. 2B is a schematic cross-sectional view of an optical module 200B according to one or more aspects of the present disclosure. The optical module 200B can be used in a data center, for example. The optical module 200B is configured in a same manner as the optical module 200A of FIG. 2A, except as otherwise provided below. In one or more examples, as will be described below, the optical module 200B can include a hermetic metal cover disposed on a single layer carrier, with mounting of the cover and carrier within a cutout of the PCB, e.g., by soldering or gluing. In such examples, the PCB can be electrically coupled with an EIC through wire bonds and a buried carrier line. The cutout of the PCB can facilitate shorter wire bond and line lengths. During assembly, the top cover can be added after inserting an electro-optical package and optical component alignment.

As depicted in FIG. 2B, the optical module 200B can include, among other things, a carrier package 291. The carrier package 291 can include a carrier 293, which can be formed of a ceramic or glass material and at least on electrically-conductive layer. In one or more examples, the carrier 293 can be a single layer carrier, e.g., having a single electrically-conductive layer. The carrier package 291 can also include standoffs 295 that are coupled with the cover 220, e.g., by bonding, gluing, etc. The carrier package 291 can be disposed, at least in part, within a cutout 215 defined by the PCB 210. Also, the cover 220 can be disposed, at least in part, within the cutout 215. In at least one example, the cutout 215 can extend between a top side 212 and a bottom side 214 of the PCB 210. In one or more examples, the fiber dock 221 of the cover 220 can be seated on the top side 212 of the PCB 210.

In at least one example, at least one of the standoffs 295 and the carrier 293 can undergo brazing to couple them, with a filler material being used to create a buried carrier line 297, which can be formed of an electrically-conductive material. The wire bond 218 can electrically connect the EIC 262 with the buried carrier line 297. The buried carrier line 297 can traverse between the carrier 293 and the standoff 295, e.g., along the X-direction, to a position that is not underneath the cover 220. As shown in FIG. 2B, the buried carrier line 297 can extend beyond the standoff 295 and away from the sealed interior 230, e.g., along the X-direction, between an extension portion 299 of the carrier 293 and the bottom side 214 of the PCB 210. The extension portion 299 is a part of the carrier 293 that extends underneath the bottom side 214 of the PCB 210, or rather, to a position that is not underneath the cover 220. The buried carrier line 297 can be electrically coupled with the buried transmission line 216, e.g., at the bottom side 214 of the PCB 210. Accordingly, the EIC 262 can be electrically coupled with the PCB 210 by way of an electrical path 296 that extends, at least in part, through the carrier 293 by way of the buried carrier line 297. The buried carrier line 297 can be electrically coupled with the PCB 210, e.g., by way of a leadless interconnect 289 of the carrier package 291 at the bottom side 214 of the PCB 210.

The architecture of the optical module 200B can advantageously provide increased signal and power integrity as the signal lines spanning between the electro-optical package 240 and one or more devices external to the sealed interior 230 are not in contact with the immersion fluid F1 and thus are not or negligibly impacted by phase changes of the immersion fluid F1. That is, the signal lines are protected from the immersion fluid F1. Moreover, the carrier 293, which can be a single layer carrier, can provide a one-layer routing substrate.

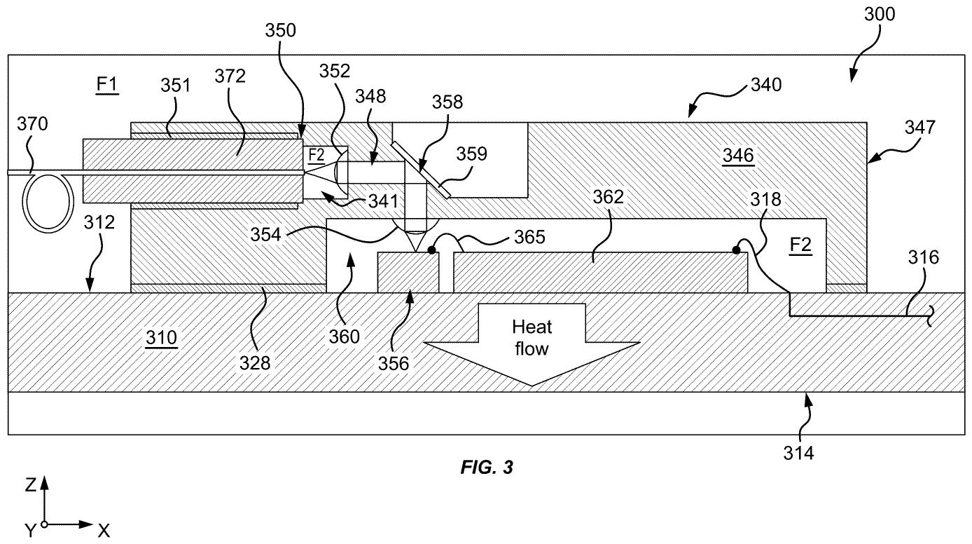

FIG. 3 is a schematic cross-sectional view of an optical module 300 according to one or more aspects of the present disclosure. The optical module 300 can be used in a data center, for example. In one or more examples, as will be described below, the optical module 300 can include a lens body utilized as a hermetic housing that encloses certain electro-optical components to protect the optical path from immersion fluid. A mirror coating can be applied to a reflective surface of the lens body to achieve desired reflectance along a free-space optical path. In such examples, the lens body is not encased within a sealed interior by a cover. Rather, external surfaces of the lens body can be exposed to the immersion fluid.

As illustrated in FIG. 3, the optical module 300 can include a PCB 310 and an electro-optical package 340 disposed on the PCB 310. The PCB 310 has a first side 312 and a second side 314 opposite the first side 312. The PCB 310 and the electro-optical package 340 are disposed in an immersion fluid F1. In this regard, the outer or external surfaces of the PCB 310 and electro-optical package 340 can be exposed to the immersion fluid F1.

The electro-optical package 340 can include a lens body 346. The immersion fluid F1 can contact external surfaces 347 of the lens body 346. A sealing gasket 328 or adhesive can be used to seal the lens body 346 to the PCB 310. The lens body 346 and the PCB 310 can collectively define an enclosure 360 that is sealed off from the immersion fluid F1. In one or more examples, optical fluid F2 can be disposed within the enclosure 360.

The electro-optical package 340 can include a lens body 346 providing an optical path 348 along which optical signals can travel. The lens body 346 can be formed of polyetherimide or another thermoplastic material, for example. Accordingly, in such examples, the optical path 348 can be considered a guided optical path.

An optical connector 372 (e.g., a ferrule, fiber array unit, etc.) of an optical fiber 370 can be received by the lens body 346. In at least one example, the lens body 346 can define a pocket 350 in which the optical connector 372 can be received. The optical connector 372 can be arranged to link the optical fiber 370 with the optical path 348. A sealant 351 can encase the optical connector 372 within the pocket 350, and in at least one example, adhere the optical connector 372 to the lens body 346. In this regard, the sealant 351 can be an adhesive sealant. The lens body 346 can also define a free-space channel 341 that is contiguous with the pocket 350. The sealant 351 can prevent immersion fluid F1 from entering the free-space channel 341.

The lens body 346 can have the first lens 352 (or a plurality of first lenses) disposed along the optical path 348. The first lens 352 can be arranged in direct optical communication with the optical connector 372. The optical connector 372 can be spaced from the first lens 352, e.g., by a distance along the X-direction. The free-space channel 341 can allow for optical signals to travel between the optical fiber 370 and the first lens 352. The lens body 146 can also include a second lens 354 (or a plurality of second lenses) disposed along the optical path 348. The second lens 354 can be arranged in direct optical communication with a modulator 356 of the electro-optical package 340. Further, the lens body 346 can include a reflective surface 358 disposed between the first and second lenses 352, 354 along the optical path 348 and arranged to change a direction of optical signals, e.g., by ninety degrees (90°). The reflective surface 358 can have a coated backing 359 that separates the immersion fluid F1 from the reflective surface 358.

The electro-optical package 340 can further include an EIC 362, disposed within the enclosure 360 and arranged on, and electrically coupled with, the PCB 310. The EIC 362 can include a TIA and a driver, which can be arranged on the same or different chips. The modulator 356 can include one or more photodetectors and one or more light emitters, such as VCSELs. The modulator 356 can be electrically coupled with the EIC 362, e.g., by wire bonds 365, and can be optically coupled with the optical path 348. For instance, the photodetectors of the modulator 356 can be components of a receiver circuit and can convert incoming optical signals from the optical path 348 into electrical signals, which can be routed to the TIA for processing, e.g., by wire bonds 365. The light emitters can be components of a transmitter circuit and can convert electrical signals received from the driver into optical signals, which can be transmitted to the optical path 348 and to an optical fiber associated with the transmitter circuit. Accordingly, the modulator 356 can be arranged to convert optical signals into electrical signals and electrical signals into optical signals.

In one or more examples, the EIC 362 can be directly mounted on the PCB 310. As shown in FIG. 3, the heat generated by the electro-optical package 340, including by the EIC 362 and the modulator 356, can conduct through the thickness of the PCB 310 and can be imparted to the relatively cool immersion fluid F1. In this way, the thermal performance of the optical module 300 can be enhanced. In one or more examples, the second side 314 of the PCB 310 can be metal plated, e.g., to enhance the conductive heat transfer and to prevent or reduce vapor contaminate into the enclosure 360.

In one or more examples, the PCB 310 can have one or more buried transmission lines 316 (only one shown in FIG. 3). The buried transmission lines 316 can be electrically coupled with the EIC 362, e.g., by respective wire bonds 318 extending from the EIC 362, and can each be electrically coupled with other devices arranged external to the enclosure 360. In at least one example, at least one of the buried transmission lines 316 can extend from a starting position underneath the lens body 346 to an ending position not underneath the lens body 346. In FIG. 3, one of the buried transmission lines 316 is shown extending to a position not underneath the lens body 346.

The architecture of the optical module 300 can advantageously provide an optical assembly unconstrained by a cover, allowing for immersion fluid F1 to directly contact and cool, among other things, external surfaces of the lens body 346. This can enhance the cooling performance of the optical module 300. Moreover, the architecture of the optical module 300 can provide free space optical coupling between the optical fiber 370 and the lens body 346 and between the lens body 346 and the modulator 356, with both of these free space optical couplings being within optical fluid F2 that is fluidly isolated from, and different than, the immersion fluid F1. In this way, multimode optical signals can travel along the guided optical path 348 of the lens body 346 and the free space optical couplings can be shielded from negative impacts from phase changes of the immersion fluid F1. Further, the reflective surface 358 can include a coating or coated backing 359 to prevent or reduce interference of the immersion fluid F1 with the optical signals traveling along the guided optical path 348.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s).

In view of the foregoing, the scope of the present disclosure is determined by the claims that follow.

We claim:

1. An optical module, comprising:
a printed circuit board (PCB);
a cover having a flange coupled with the PCB, wherein the PCB and the cover are sealed such that when the PCB and the cover are disposed in an immersion fluid the PCB and the cover collectively define a sealed interior that is fluidly isolated from the immersion fluid;
an optical fiber;
a modulator; and
a lens body disposed in the sealed interior and providing an optical path along which optical signals travel, wherein the optical fiber is in free space optical communication with the optical path of the lens body and the modulator is in free space optical communication with the optical path,
wherein a fiber escape is formed by the flange and the PCB, allowing the optical fiber to escape the sealed interior into the immersion fluid.

2. The optical module of claim 1, wherein the flange of the cover has an escape section and a mounting section, and wherein the escape section forms, at least in part, the fiber escape and is arranged further from the PCB than the mounting section.

3. The optical module of claim 1, further comprising:
a sleeve arranged to protect the optical fiber as the optical fiber passes through the fiber escape.

4. The optical module of claim 1, wherein the PCB has a first side and a second side opposite the first side, and wherein the cover and the lens body are arranged on the first side of the PCB, and wherein the optical module further comprises:
a compression plate disposed on the second side of the PCB; and
one or compression elements extending through the PCB and compressing the cover and the compression plate toward one another.

5. The optical module of claim 4, wherein the compression plate forms one or more openings that allow immersion fluid to directly contact the second side of the PCB.

6. The optical module of claim 1, wherein the immersion fluid is a dual-phase immersion fluid.

7. The optical module of claim 1, wherein the lens body has a lens and defines a free-space channel disposed between the optical fiber and the lens, and wherein the free-space channel is filled with an optical fluid that is fluidly isolated from, and different than, the immersion fluid.

8. The optical module of claim 1, wherein the lens body and the PCB collectively define an enclosure in which the modulator is disposed, and wherein the enclosure is filled with an optical fluid that is fluidly isolated from, and different than, the immersion fluid.

9. The optical module of claim 8, further comprising:
an electrical integrated circuit (EIC) disposed within the enclosure and being electrically coupled with the modulator.

10. The optical module of claim 9, wherein the PCB has a buried transmission line that is electrically coupled with the EIC, and wherein the buried transmission line extends from a position underneath the cover to a position not underneath the cover.

11. The optical module of claim 1, wherein the lens body comprises:
a first lens disposed along the optical path and arranged in free space optical communication with the optical fiber;
a second lens disposed along the optical path and arranged in free space optical communication with the modulator; and
a reflective surface disposed between the first lens and the second lens along the optical path and arranged to change a direction of optical signals traveling along the optical path.

12. The optical module of claim 11, wherein the lens body is formed of a thermoplastic material such that the optical path is a guided optical path.

13. An optical module, comprising:
a printed circuit board (PCB);
a carrier package that includes an interconnect and a carrier having at least one electrically-conductive layer;
an optical fiber;
a cover coupled with the carrier and having a fiber dock that receives the optical fiber and defines a free space channel to provide free space optical communication between the optical fiber and a dock lens of the fiber dock, wherein the carrier and the cover are sealed such that when the PCB, the carrier, and the cover are disposed in an immersion fluid, the carrier and the cover collectively define a sealed interior that is fluidly isolated from the immersion fluid; and
an electro-optical package disposed in the sealed interior, the electro-optical package having a lens body, a modulator, and an electrical integrated circuit (EIC) arranged on, and electrically coupled with, the carrier, wherein the lens body provides an optical path that is in free space optical communication with the dock lens and in free space optical communication with the modulator,
wherein an electrical path is defined between the EIC and the PCB, at least in part, by the carrier and the interconnect.

14. The optical module of claim 13, wherein the carrier is a multilayer carrier having a plurality of electrically-conductive layers and the interconnect is one of a plurality of interconnects, and wherein the multilayer carrier is mounted on the PCB by way of the plurality of interconnects that electrically couple the PCB and the carrier.

15. The optical module of claim 14, wherein the plurality of interconnects are balls of a ball grid array.

16. The optical module of claim 13, wherein the PCB defines a cutout, and wherein the cover and the carrier are both disposed, at least in part, within the cutout.

17. The optical module of claim 13, wherein the electrical path extends through the carrier is coupled with the PCB by way of a leadless interconnect.

18. The optical module of claim 17, wherein the leadless interconnect couples the electrical path with a bottom side of the PCB.

19. An optical module, comprising:
a printed circuit board (PCB);
an optical fiber; and
an electro-optical package having a modulator and a lens body mounted on the PCB, wherein when the lens body and the PCB are disposed in an immersion fluid, external surfaces of the lens body and the PCB are exposed to the immersion fluid, wherein:
the lens body and the PCB collectively define an enclosure in which the modulator is arranged and which is sealed such that when the lens body and the PCB are disposed in immersion fluid, the enclosure is fluidly isolated from the immersion fluid;
the lens body provides a guided optical path along which optical signals travel between a first lens and a second lens of the lens body;
the lens body defines a free-space channel that allows the optical fiber to be in free space optical communication with the first lens, the free-space channel being filled with an optical fluid that is fluidly isolated from, and different than, the immersion fluid;
the second lens is in free space optical communication with the modulator; and
the lens body has a reflective surface disposed along the guided optical path and arranged to change a direction of optical signals, the reflective surface having a coated backing that fluidly isolates the immersion fluid from the reflective surface.

20. The optical module of claim 19, wherein the electro-optical package has a an electrical integrated circuit (EIC) disposed within the enclosure and electrically coupled with the modulator, and wherein the PCB has a buried transmission line that is electrically coupled with the EIC, and wherein the buried transmission line extends from a position underneath the lens body to a position not underneath the lens body.
